(19) United States
(12) Patent Application Publication
(10) Pub. No.: US 2019/0316254 A1
(43) Pub. Date: Oct. 17, 2019

(54) SUBSTRATE TREATMENT APPARATUS AND SUBSTRATE TREATMENT METHOD

(71) Applicant: EUGENE TECHNOLOGY CO., LTD., Yongin-Si (KR)

(72) Inventors: Sung Ho KANG, Hwaseong-Si (KR); Chang Dol KIM, Yongin-Si (KR); Seong Min HAN, Yongin-Si (KR); Seok Yun KIM, Yongin-Si (KR); Sung Ha CHOI, Hwaseong-Si (KR)

(21) Appl. No.: 16/292,238

(22) Filed: Mar. 4, 2019

(30) Foreign Application Priority Data
Apr. 12, 2018 (KR) 10-2018-0042857

(51) Int. Cl. C23C 16/455; C23C 16/52

(52) U.S. Cl. CPC C23C 16/45527; C23C 16/45546; C23C 16/52

(57) ABSTRACT

The present disclosure relates to a substrate treatment apparatus and a substrate treatment method, and more particularly, to a substrate treatment apparatus and a substrate treatment method configured to deposit a uniform thin film on a substrate. A substrate treatment apparatus, in accordance with an exemplary embodiment, includes a reaction tube having an internal space formed therein, a substrate boat configured to load a plurality of substrates in multi-stages, and positioned in the internal space to partition a plurality of treatment spaces in which the plurality of substrates are respectively treated, a process gas supply part configured to supply a process gas to the plurality of treatment spaces, and a dilution gas supply part configured to supply a dilution gas for diluting the process gas within the plurality of treatment spaces.

### CROSS-REFERENCE TO RELATED APPLICATION

This application claims priority to Korean Patent Application No. 10-2018-0042857 filed on Apr. 12, 2018 and all the benefits accruing therefrom under 35 U.S.C. § 119, the contents of which are incorporated by reference in their entirety.

### BACKGROUND

The present disclosure relates to a substrate treatment apparatus and a substrate treatment method, and more particularly, to a substrate treatment apparatus and a substrate treatment method configured to deposit a uniform thin film on a substrate.

In general, substrate treatment apparatuses include single-wafer type substrate treatment apparatuses that can perform a substrate treatment process on one substrate and batch type substrate treatment apparatuses that can perform a substrate treatment process on a plurality of substrates simultaneously. Single-wafer type substrate treatment apparatuses have a simple configuration of equipment, but are less productive. Thus, batch type substrate treatment apparatuses capable of mass production have been commonly used.

Batch type substrate treatment apparatuses of the related art each include a substrate boat configured to load a plurality of substrates, a reaction tube configured to receive the substrate boat and perform a substrate treatment process thereon, a gas supply part configured to supply a process gas to the inside of the reaction tube, and an exhaust part configured to exhaust a gas remaining within the reaction tube. Such a substrate treatment process using batch type substrate treatment apparatuses is performed as follows. First, a plurality of substrates are loaded into a reaction tube. Next, a gas supply part supplies a process gas to the inside of the reaction tube while an exhaust part exhausts the reaction tube. Here, the process gas supplied by the gas supply part forms thin films on the substrates while passing through between the respective substrates, and a residual gas is exhausted to the exhaust part through an exhaust opening.

However, the batch type substrate treatment apparatuses of the related art load a plurality of substrates on a substrate boat in multi-stages and perform a substrate treatment process thereon. Thus, a difference occurs between the locations at which the plurality of substrates are treated. Such a difference causes a difference to occur between the thicknesses of thin films respectively deposited on the plurality of substrates. As a result, a uniform thin film cannot be obtained when the treatment process is performed on the plurality of substrates in a batch type.

### SUMMARY

The present disclosure provides a substrate treatment apparatus and a substrate treatment method that may make uniform the thicknesses of thin films respectively deposited on a plurality of substrates loaded on a substrate boat.

In accordance with an exemplary embodiment, a substrate treatment apparatus includes: a reaction tube having an internal space formed therein, a substrate boat configured to load a plurality of substrates in multi-stages, and positioned in the internal space to partition a plurality of treatment spaces in which the plurality of substrates are respectively treated, a process gas supply part configured to supply a process gas to the plurality of treatment spaces, and a dilution gas supply part configured to supply a dilution gas for diluting the process gas within the plurality of treatment spaces.

The process gas supply part may supply the process gas to each of the plurality of treatment spaces, and the dilution gas supply part may supply the dilution gas to a portion of the plurality of treatment spaces.

The plurality of treatment spaces may be divided into an upper treatment space, a center treatment space, and a lower treatment space in a direction in which the plurality of substrates are loaded, and the dilution gas supply part may supply the dilution gas to at least one of the upper treatment space or the lower treatment space.

The dilution gas supply part may include: an upper dilution gas supply part having an upper dilution gas supply hole corresponding to the upper treatment space; and a lower dilution gas supply part having a lower dilution gas supply hole corresponding to the lower treatment space.

The substrate treatment apparatus may further include: an exhaust duct disposed opposing the process gas supply part, and formed to extend vertically in a direction in which the plurality of substrates are loaded; and an exhaust port configured to communicate with a lower end of the exhaust duct. The process gas supply part may be formed to extend vertically in the direction in which the plurality of substrates are loaded, and the process gas may flow from a lower end of the process gas supply part to an upper end thereof, may pass through each of the plurality of treatment spaces, may flow from an upper end of the exhaust duct to the lower end thereof, and may be exhausted through the exhaust port.

Dummy substrates may be loaded on an upper end portion and a lower end portion of the substrate boat, and the plurality of treatment spaces may be provided between the upper end portion and the lower end portion of the substrate boat.

The dilution gas supply part may supply the dilution gas in a direction crossing a direction in which the process gas is supplied on the plurality of substrates.

The substrate treatment apparatus may further include a control part connected to the dilution gas supply part, and configured to control the amount of the dilution gas supplied by the dilution gas supply part. The control part may be configured to control such that the amount of the dilution gas supplied by the lower dilution gas supply part is greater than the amount of the dilution gas supplied by the upper dilution gas supply part.

The substrate treatment apparatus may further include a heater part provided outside the reaction tube in the direction in which the plurality of substrates are loaded, and configured to heat the plurality of treatment spaces. The heater part may be configured to heat the upper treatment space and the lower treatment space at a temperature lower than that at which the center treatment space is heated.

In accordance with an exemplary embodiment, a substrate treatment method includes: respectively positioning a plurality of substrates in a plurality of treatment spaces disposed in multi-stages; and forming thin films on the plurality of substrates by supplying a process gas to the plurality of treatment spaces. The forming of the thin films includes supplying a dilution gas for diluting the process gas within the plurality of treatment spaces.

The forming of the thin films may further include: supplying a raw gas to the plurality of treatment spaces; purging the raw gas remaining in the plurality of treatment spaces; supplying a reaction gas to the plurality of treatment spaces; and purging the reaction gas remaining in the plurality of treatment spaces, and the supplying of the dilution gas may be performed at least together with the supplying of the raw gas.

The plurality of treatment spaces may be divided into an upper treatment space, a center treatment space, and a lower treatment space in a direction in which the plurality of substrates are loaded, and the supplying of the dilution gas may include supplying the dilution gas to at least one of the upper treatment space or the lower treatment space.

The purging of the raw gas and the purging of the reaction gas may be performed by repeating supply and shutoff of a purge gas to the plurality of treatment spaces multiple times while exhausting the plurality of treatment spaces.

The dilution gas and the purge gas may each include a gas chemically stable with respect to the raw gas and the reaction gas, and the supplying of the dilution gas may include supplying the dilution gas to the plurality of treatment spaces through a path different from that through which the purge gas is supplied thereto.

The supplying of the reaction gas may include: simultaneously supplying a first reaction gas and a second reaction gas to the plurality of treatment spaces; and solely supplying the second reaction gas to the plurality of treatment spaces.

According to exemplary embodiments, the substrate treatment apparatus and the substrate treatment method in accordance with the exemplary embodiments, may supply the dilution gas together with the process gas to the plurality of treatment spaces partitioned by the substrate boat, thereby controlling the concentration of the process gas, and may supply the dilution gas to the portion of the plurality of treatment spaces to adjust the concentration of the process gas in each treatment space, thereby individually controlling the thicknesses of the thin films deposited on the plurality of substrates loaded.

That is, the thicknesses of the thin films deposited on the substrates loaded in each treatment space may be made uniform regardless of the presence of the process gas staying the extra internal spaces formed in upper portions and lower portions of the plurality of treatment spaces within the reaction tube of a longitudinal type, and, even when the process gas flowed from the lower end of the process gas supply part is discharged through the exhaust port positioned in the lower portion of the internal space via the plurality of treatment spaces, the thicknesses of the portions of the thin films deposited in the upper treatment space and the lower treatment space may be made uniform with that of a portion of the thin films deposited in the center treatment space. Furthermore, even when substrates of a type different from that of the substrates to be treated are loaded in the upper end portion and the lower end portion of the substrate boat, uniform thin films may be formed on the substrates to be treated, respectively, thereby increasing quality of the formed thin films and the substrates, on which the thin films are formed.

Further, the upper dilution gas supply part configured to supply the dilution gas to the upper treatment space of the plurality of treatment spaces and the lower dilution gas supply part configured to supply the dilution gas to the lower treatment space thereof may be separately disposed, thereby independently controlling the concentrations of the process gas supplied to the upper treatment space and the lower treatment space, and the direction in which the process gas is supplied and the direction in which the dilution gas is supplied may be crossed on the substrates, thereby efficiently mixing, with the dilution gas, the process supplied to the respective substrates.

Moreover, in supplying different types of reaction gases during deposition of the thin films using the ALD process, mixing of the first reaction gas with the second reaction gas, supplying of the mixture, and independent supplying of the second reaction gas may be sequentially performed, thereby effectively controlling the content of the element contained in the thin films from the first reaction gas, and, the plurality of treatment spaces may be quickly depressurized and the raw gas remaining in each treatment space may be effectively and sufficiently replaced with the stable gas by repeating the supply and shutoff of the purge gas to the plurality of treatment spaces multiple times while exhausting the plurality of treatment spaces in the purging of the raw gas or the reaction gas.

### BRIEF DESCRIPTION OF THE DRAWINGS

Exemplary embodiments can be understood in more detail from the following description taken in conjunction with the accompanying drawings, in which:

FIG. 1 is a view schematically illustrating a substrate treatment apparatus in accordance with an exemplary embodiment;

FIG. 2 is a graph illustrating the thicknesses of thin films deposited according to the locations of a plurality of substrates loaded in a substrate boat;

FIG. 3 is a view illustrating the shapes of a process gas supply part and a dilution gas supply part in accordance with an exemplary embodiment;

FIG. 4 is a view illustrating a direction in which a dilution gas is supplied in accordance with an exemplary embodiment;

FIG. 5 is a graph illustrating relative thicknesses of thin films deposited on the substrates according to the amounts of the dilution gas supplied in accordance with an exemplary embodiment; and

FIG. 6 is a diagram illustrating a gas supply sequence of a substrate treatment method in accordance with an exemplary embodiment.

### DETAILED DESCRIPTION OF EMBODIMENTS

Hereinafter, embodiments of the present invention will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Like reference numerals refer to like elements throughout.

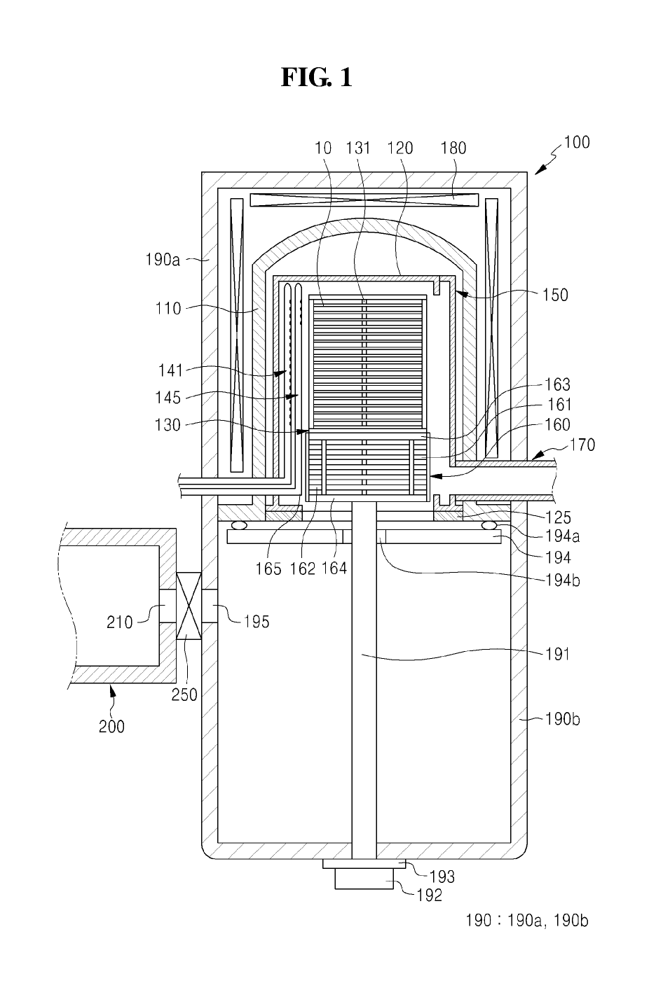

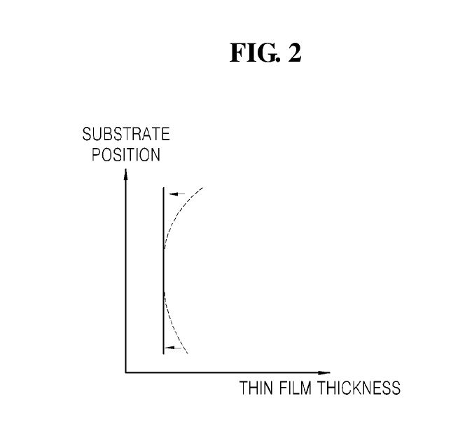

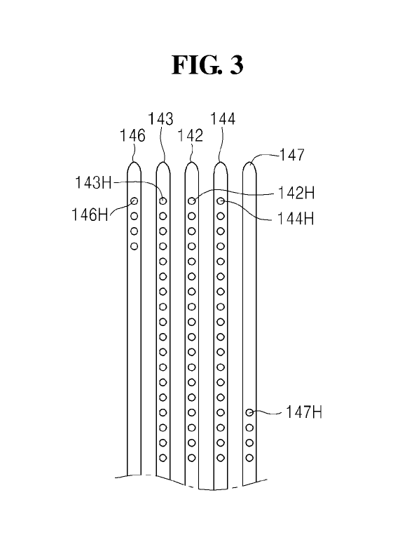

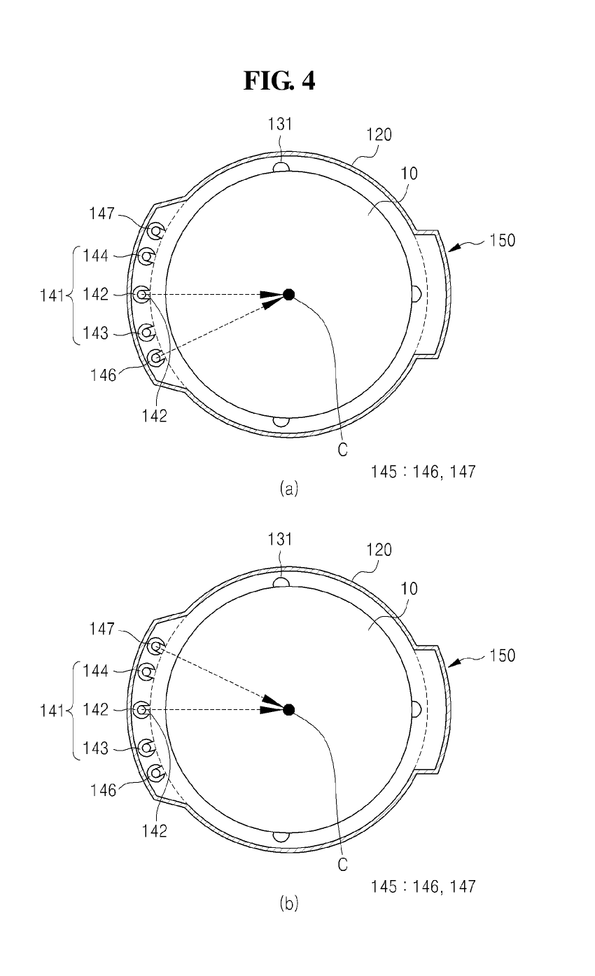

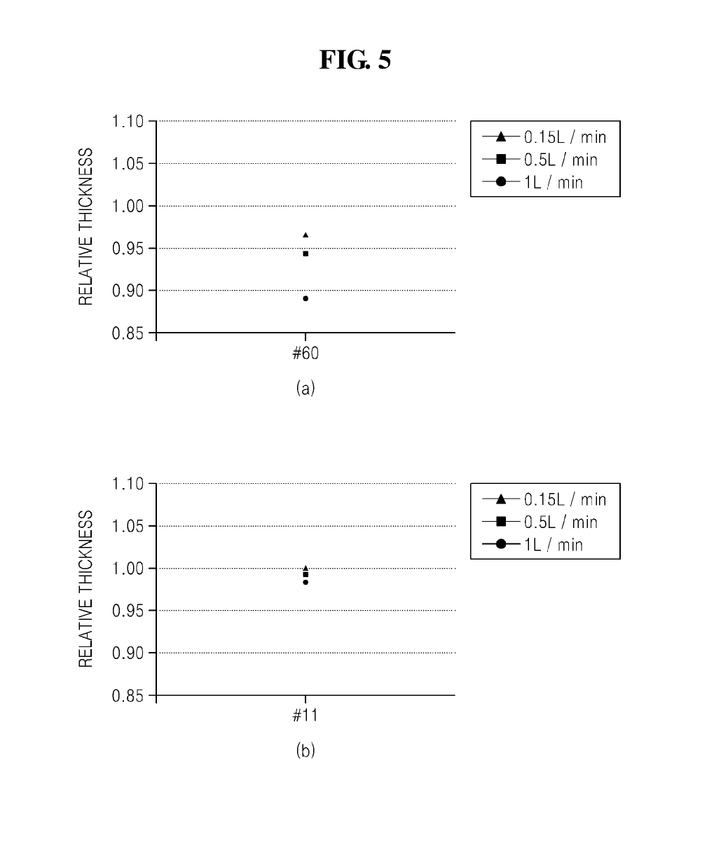

FIG. 1 is a view schematically illustrating a substrate treatment apparatus in accordance with an exemplary embodiment, and FIG. 2 is a graph illustrating the thicknesses of thin films deposited according to the locations of a plurality of substrates loaded in a substrate boat. In addition, FIG. 3 is a view illustrating the shapes of a process gas supply part and a dilution gas supply part in accordance with an exemplary embodiment, and FIG. 4 is a view illustrating a direction in which a dilution gas is supplied in accordance with an exemplary embodiment. FIG. 5 is a graph illustrating relative thicknesses of thin films deposited on the substrates according to the amounts of the dilution gas supplied in accordance with an exemplary embodiment.

Referring to FIGS. 1 to 5, a substrate treatment apparatus 100 in accordance with an exemplary embodiment includes: a reaction tube 120 having an internal space formed therein; a substrate boat 130 configured to load a plurality of substrates 10 in multi-stages, and positioned in the internal space to partition a plurality of treatment spaces in which the plurality of substrates 10 are respectively treated; a process gas supply part 141 configured to supply a process gas to the plurality of treatment spaces; and a dilution gas supply part 145 configured to supply a dilution gas for diluting the process gas.

An external tube 110 may be provided outside the reaction tube 120, the external tube 110 has a receiving space in which the reaction tube 120, in which a process of treating the substrates 10 is performed, may be received, and a lower portion of the external tube 110 may open.

The reaction tube 120 may be disposed in the receiving space of the external tube 110 while being spaced apart from an internal surface of the external tube 110, and may have the internal space in which the substrate boat 130 is loaded. The reaction tube 120 may be formed in a cylindrical shape, may have a lower portion opened with an upper portion closed, and may allow the substrate boat 130 to be loaded or unloaded from a receiving space of the reaction tube 120 through an opening portion of the lower portion of the reaction tube 120 when the substrate boat 130 is lifted in order to be loaded in the internal space of the reaction tube 120 in which the process of treating the substrates 10 is performed. The lower portion of the reaction tube 120 may be connected to a flange part 125 to be supportable thereby, and the structure and shape of the reaction tube 120 are not limited thereto, and may be variously formed.

Meanwhile, the reaction tube 120 may be formed of ceramics or a material in which quartz or metal is coated with ceramics, the process gas supply part 141 and the dilution gas supply part 145 are disposed on one side of the internal space of the reaction tube 120, and an exhaust opening of an exhaust duct 150 may be provided on the other side opposing the one side. Thus, a gas remaining within the reaction tube 120 may be exhausted to the outside through the exhaust opening.

The substrate boat 130 may allow the plurality of substrates 10 to be loaded in a vertical direction in multi-stages in order to perform the process of treating the substrates 10 in a batch type, and is positioned in the internal space of the reaction tube 120 during treatment of the substrates 10 to partition the plurality of treatment spaces in which the plurality of substrates are respectively treated. That is, the plurality of substrates 10 are loaded in the substrate boat 130 in the vertical direction in multi-stages, and the plurality of treatment spaces are partitioned by the plurality of substrates 10 loaded in the substrate boat 130. Here, the treatment spaces refer to spaces in which the process of treating the substrates 10 is individually performed, and the process gas is supplied from a plurality of process gas supply holes formed in the process gas supply part 141 to each of the plurality of treatment spaces.

For example, the substrate boat 130 may have slots formed in a plurality of rods 131 in multi-stages such that the substrates 10 may be inserted and loaded in the substrate boat 130, and may also be configured such that isolation plates (not illustrated) may be disposed on upper or lower sides of the substrates 10, respectively, and the substrates 10 may thus have individual treatment spaces, respectively. Here, the isolation plates (not illustrated) may independently partition the plurality of treatment spaces in which the substrates 10 are respectively treated, and the substrates 10 may be loaded by being supported by support protrusions (not illustrated) formed on the isolation plates (not illustrated), and may also be loaded by being inserted or supported by components such as the slots, support tips (not illustrated), and the like formed on the plurality of rods 131. When the substrate boat 130 has the isolation plates (not illustrated), the plurality of treatment spaces for the substrates 10 may be independently formed in respective stages (or layers) of the substrate boat 130 to prevent the interference between the treatment spaces from occurring.

Meanwhile, the substrate boat 130 may also rotate during the treatment of the substrates 10, and ceramics, quartz, synthetic quartz, and the like may be used as a material of the substrate boat 130 including the rods 131, the isolation plates (not illustrated), and the like. However, the structure, shape, and material of the substrate boat 130 are not limited thereto, and may vary.

A pedestal 160 may be connected to a lower end portion of the substrate boat 130 to support the substrate boat 130, may be raised together with the substrate boat 130, and may be received in a lower end portion of the internal space of the reaction tube 120 during the treatment of the substrates 10. The pedestal 160 may include a plurality of heat shielding plates 161 spaced apart from each other to be disposed in multi-stages. The plurality of heat shielding plates 161 may be connected to a plurality of supports 162 to be disposed in multi-stages, may be spaced apart from each other, may be formed as baffle plates configured to prevent transfer of heat in a vertical direction, and may be formed of a material (for example, opaque quartz) having a low heat conduction. For example, the heat shielding plates 161 may have a disc shape, and may be fixed to the plurality of supports 162 at intervals in a vertical direction. The pedestal 160 may block, through the plurality of heat shielding plates 161, transfer of heat from the receiving space of the internal space of the reaction tube 120 that receives the substrate boat 130.

Further, the pedestal 160 is formed to extend in a vertical direction, and may further include the plurality of supports 162 disposed spaced apart from each other, an upper plate 163 and a lower plate 164 configured to fix an upper end and a lower end of the plurality of supports 162, respectively, and a lateral cover 165 configured to surround lateral surfaces of the plurality of heat shielding plates 161 (or a lateral surface of the pedestal 160). The plurality of supports 162 may be formed to extend in a vertical direction, may be disposed spaced apart from each other in a horizontal direction, and may support the plurality of heat shielding plates 161. For example, the plurality of supports 162 may be formed as four supports, and may have a plurality of slots formed in a vertical direction such that the plurality of heat shielding plates 161 may be inserted into the plurality of slots, respectively, to be supported thereby.

The upper plate 163 may fix the upper end of the plurality of supports 162, and may be connected to the substrate boat 130. For example, the substrate boat 130 may be placed on the upper plate 163 to be supported thereby (or fixed thereto). The lower plate 164 may fix the lower end of the plurality of supports 162, and may be connected (or attached) to a shaft 192. For example, the substrate boat 130 may be rotated while the pedestal 160 is rotated by rotation of the shaft 191 connected to the lower plate 164. Here, the plurality of supports 162, the upper plate 163, and the lower plate 164 may form a frame of the pedestal 160.

The lateral cover 165 may be formed to surround the lateral surfaces of the plurality of heat shielding plates 161 (or the lateral surface of the pedestal 160), and may be connected to the upper plate 163 and/or the lower plate 164 to be fixed thereto. The lateral cover 165 may block a gas such as a residual gas from flowing to spaces between the plurality of heat shielding plates 161, thereby preventing internal pollution of the pedestal 160 due to the residual gas, as well as preventing transfer of heat due to convection through insulation. Further, when the lateral cover 165 protrudes further than the edge (or the circumference) of the substrate boat 130, the lateral cover 165 may inhibit the process gas supplied to the inside of the reaction tube 120 from escaping to a lower portion (a space between a side wall of the reaction tube 120 and the lateral surface of the pedestal 160) while the process gas does not reach the substrates 10 and react therewith.

The pedestal 160 may block transfer of heat due to convection through the lateral cover 165 while blocking transfer of heat due to conduction, as well as transmission of heat due to radiation through the plurality of heat shielding plates 161. Thus, the pedestal 160 may block transfer of heat (or leakage of heat) from the plurality of treatment spaces partitioned by the substrate boat 130, and the plurality of substrates 10 may be treated stably and uniformly.

The process gas supply part 141 may be disposed on the one side of the internal space of the reaction tube 120, and may supply the process gas to the inside of the reaction tube 120. Here, the process gas supply part 141 has a structure in which the process gas is supplied to each of the plurality of treatment spaces partitioned by the substrate boat 130 and the supplied process gas is exhausted to an exhaust port 170 via each of the plurality of treatment spaces. Here, the process gas may include a raw gas, a reaction gas, and a purge gas. To this end, a gas supply part may include a raw gas supply part 142 and reaction gas supply parts extending vertically in a direction in which the plurality of substrates 10 are loaded. The raw gas supply part 142 and the reaction gas supply parts may be disposed in a nozzle receiving space formed on one side of the internal space of the reaction tube 120. Thus, the volume of the internal space of the reaction tube 120 may be minimized, thereby concentrating the process gas on the treatment spaces for the substrates 10 loaded in the substrate boat 130 while minimizing the amount of the process gas used to treat the substrates 10.

Further, the process gas supply part 141 may also include a separate purge gas supply part configured to supply the purge gas. However, the substrate treatment apparatus 100 in accordance with an exemplary embodiment may supply the purge gas through the raw gas supply part 142 or the reaction gas supply parts 143 and 144. That is, the purge gas may be supplied to each treatment space by the raw gas supply part 142 or the reaction gas supply parts 143 and 144 when the raw gas or the reaction gas is not supplied by the raw gas supply part 142 or the reaction gas supply parts 143. The process gas may be supplied to each treatment space through raw gas supply holes 142H and reaction gas supply holes 143H and 144H respectively formed in the raw gas supply part 142 and the reaction gas supply parts 143 and 144. The raw gas supply holes 142H and the reaction gas supply holes 143H and 144H may be formed in pluralities in a direction in which the raw gas supply part 142 extends to face the plurality of treatment spaces, and may be formed such that the process gas is supplied to all of the plurality of treatment spaces.

In more detail, the raw gas supply part 142 and the reaction gas supply parts may be formed as “L”-shaped nozzles each having a horizontal portion and a vertical portion. Here, the horizontal portion is provided through the side wall of the reaction tube 120, and the vertical portion is formed to extend vertically in the direction in which the substrates 10 are loaded in the substrate boat 130 in the internal space of the reaction tube 120. Further, the raw gas supply part 142 and the reaction gas supply parts are provided spaced apart from each other at predetermined distances along the outer circumferences of the substrates 10.

The raw gas supply holes 142H and the reaction gas supply holes 143H and 144H are formed in lateral surfaces of the respective vertical portions of the raw gas supply part 142 and the reaction gas supply parts 143 and 144 over all areas of the lateral surfaces from the top to the bottom to correspond the plurality of treatment spaces and oppose the respective treatment spaces (or the substrates 10). For example, when 65 substrates 10 are loaded in the substrate boat 130, the treatment spaces are partitioned into 65 treatment spaces by the substrate boat 130, and 65 raw gas supply holes 142H and 65 reaction gas supply holes 143H and 144H are formed in the lateral surfaces of the respective vertical portions of the raw gas supply part 142 and the reaction gas supply parts towards the respective treatment spaces.

Here, the raw gas supply holes 142H and the reaction gas supply holes 143H and 144H may be formed to spray the raw gas and the reaction gas, respectively, towards a center portion of each of the plurality of substrates 10. Further, each of the raw gas supply holes 142H and the reaction gas supply holes 143H and 144H may have the same opening area, and may be provided at the same intervals. Such a configuration may promote supply of the raw gas and the reaction gas to the center portion of each substrate 10, and the flow rate or flow velocity of the raw gas and the reaction gas supplied to each substrate 10 may be made uniform, thereby easily controlling the flow rate of the dilution gas supplied by the dilution gas supply part 145 to be described later.

The dilution gas supply part 145 are provided distinct from the process gas supply part 141 to supply the dilution gas for diluting the process gas within the treatment spaces to reduce the concentration of the process gas.

Since extra internal spaces are provided in upper and lower portions of the plurality of treatment spaces partitioned by the substrate boat 130 within the reaction tube 120 of a longitudinal type, and the process gas is easy to stay in the extra internal spaces, in the case of the conventional substrate treatment apparatus of the related art, a portion of the substrates 10 loaded in the upper treatment space are in contact with a great amount of process gas, compared to a portion of the substrates 10 loaded in the center treatment space.

Further, since the substrate treatment apparatus of the related art has a structure in which the process gas supplied and remaining in the plurality of treatment spaces is exhausted to the exhaust port 170 provided to communicate with the internal space in a lower portion of the internal space of the reaction tube 120, a period during which the process gas stays in the upper treatment space of the plurality of treatment spaces is increased. Thus, the thicknesses of the thin films deposited on the portion of the substrates 10 loaded in the upper treatment space are increased. Furthermore, the raw gas supply part 142 and the reaction gas supply parts as described above are formed to extend vertically in the direction in which the plurality of substrates 10 are loaded, and the raw gas supply holes 142H and the reaction gas supply holes 143H and 144H are formed in the raw gas supply part 142 and the reaction gas supply parts in the direction in which the plurality of substrates 10 are loaded. In this case, since the raw gas and the reaction gas are supplied from lower ends of the raw gas supply part 142 and the reaction gas supply parts, the amounts of the raw gas and the reaction gas supplied and sprayed from the raw gas supply holes 142H and the reaction gas supply holes 143H and 144H are increased in the lower treatment space of the plurality of treatment spaces. Thus, the thicknesses of the thin films deposited on a portion of the substrates 10 loaded in the lower treatment space are also increased.

As described above, since the plurality of substrates respectively loaded in the plurality of treatment spaces have a process variable depending on a difference between the locations of the substrates, the thin films are deposited on the portions of the substrates 10 loaded in the upper treatment space and the lower treatment space of the plurality of treatment spaces at a thickness relatively greater than that of the thin films deposited on the portion of the substrates 10 loaded in the center treatment space as illustrated in dotted lines in FIG. 2.

In addition, since an upper end portion and the lower end portion of the substrate boat 130 are difficult to maintain a uniform temperature distribution, the dummy substrates having a type different from that of the substrates 10 to be treated, for example, different in whether a pattern is formed thereon or in a degree to which the pattern is formed thereon, are disposed. The substrates 10 to be treated disposed between the dummy substrates have different properties from those of the dummy substrates, and a difference thus occurs between the amounts of the process gas consumed. For example, when the substrates to be treated have a relatively great surface area than the dummy substrates depending on the pattern or the like, the substrates 10 to be treated consume a relatively more process gas. Thus, the plurality of treatment spaces, in which the process of treating the substrates 10 is substantially performed and the substrates 10 to be treated are loaded, are provided between the upper end portion and the lower end portion of the substrate boat, and a more process gas remains in the upper treatment space and the lower treatment space, compared to the center treatment space. As a result, the thin films are deposited on the portions of the substrates 10 disposed in the upper treatment space and the lower treatment space at a thickness greater than that of the thin films deposited on the portion of the substrates 10 disposed in the center treatment space, and it is difficult to form, at a uniform thickness, thin films on the plurality of substrates 10, on which the treatment process is to be performed.

Thus, the substrate treatment apparatus 100 in accordance with an exemplary embodiment includes the dilution gas supply part 145 configured to supply the dilution gas for diluting the process gas independently of the process gas supply part 141 configured to supply the process gas, thereby uniformly controlling the thicknesses of the thin films deposited on the substrates 10 respectively loaded in the plurality of treatment spaces. That is, the substrate treatment apparatus 100 in accordance with an exemplary embodiment may allow the process gas supply part 141 to supply the process gas to each of the plurality of treatment spaces and allow the dilution gas supply part 145 to supply the dilution gas to the portion of the plurality of treatment spaces to reduce the concentration of the process gas supplied to the substrates 10 loaded in the treatment spaces to which the dilution gas is supplied to reduce the thicknesses of the thin films formed on the substrates 10, thereby uniformly controlling the thicknesses of the thin films deposited on the substrates 10 respectively loaded in the plurality of treatment spaces.

Here, the plurality of treatment spaces may be divided into the upper treatment space, the center treatment space, and the lower treatment space in the direction in which the plurality of substrates 10 are loaded in the substrate boat 130. That is, the upper treatment space refers to a predetermined number of treatment spaces sequentially arranged from an uppermost treatment space to a lower side thereof, of the plurality of treatment spaces in the direction in which the plurality of substrates 10 are loaded, and the lower treatment space refers to a predetermined number of treatment spaces sequentially arranged from a lowermost treatment space to an upper side thereof, of the plurality of treatment spaces in the direction in which the plurality of substrates 10 are loaded. Further, the center treatment space refers to a predetermined number of treatment spaces disposed between the upper treatment space and the lower treatment space.

Here, a method may also be considered that increases the concentration of the process gas supplied to the center treatment space in order to uniformly control the thicknesses of the thin films deposited on the substrates 10 loaded in the upper treatment space, the center treatment space, and the lower treatment space. However, in this case, a problem occurs in which it is difficult to individually control the thicknesses of the thin films deposited on the portion of the substrates 10 loaded in the upper treatment space and the thicknesses of the thin films deposited on the portion of the substrates 10 loaded in the lower treatment space. Thus, the dilution gas supply part 145 in accordance with an exemplary embodiment may supply the dilution gas to at least one of the upper treatment space or the lower treatment space, thereby individually controlling the thicknesses of portions of the thin films deposited in the upper treatment space and the lower treatment space.

To separately supply the dilution gas for diluting the process gas to the upper treatment space and the lower treatment space, the dilution gas supply part 145 may include an upper dilution gas supply part 146 having upper dilution gas supply holes 146H formed to correspond to the upper treatment space and a lower dilution gas supply part 147 having lower dilution gas supply holes 147H formed to correspond to the lower treatment space.

The upper dilution gas supply part 146 and the lower dilution gas supply part 147 may be formed as “L”-shaped nozzles each having a horizontal portion and a vertical portion as in the raw gas supply part 142 and the reaction gas supply parts. Here, the upper dilution gas supply holes 146H and the lower dilution gas supply holes 147H are formed in lateral surfaces of the respective vertical portions of the upper dilution gas supply part 146 and the lower dilution gas supply part 147. The upper dilution gas supply part 146 has the upper dilution gas supply holes 146H formed only in a section thereof corresponding to the upper treatment space, and the lower dilution gas supply part 147 has the lower dilution gas supply holes 147H formed only in a section thereof corresponding to the lower treatment space. Here, the upper dilution gas supply holes 146H and the lower dilution gas supply holes 147H may each be formed in an amount of, for example, 10 to 15, when the treatment spaces are partitioned into 65 treatment spaces as described above.

The vertical portions of the upper dilution gas supply part 146 and the lower dilution gas supply part 147 may extend to have the same length in the direction in which the substrates 10 are loaded. Here, the upper dilution gas supply part 146 supplies the dilution gas to the portion of the substrates 10 disposed in the upper treatment space, of the plurality of substrates 10 respectively loaded in the plurality of treatment spaces, thereby diluting the process gas supplied to the upper treatment space, and the lower dilution gas supply part 147 supplies the dilution gas to the portion of the substrates 10 disposed in the lower treatment space, of the plurality of substrates 10 respectively loaded in the plurality of treatment spaces, thereby diluting the process gas supplied to the lower treatment space. Here, the upper dilution gas supply holes 146H are not formed in sections of the upper dilution gas supply part 146, corresponding to the center treatment space and the lower treatment space, and the lower dilution gas supply holes 147H are not formed in sections of the lower dilution gas supply part 147, corresponding to the upper treatment space and the center treatment space.

Here, the upper dilution gas supply part 146 and the lower dilution gas supply part 147 may be disposed on both sides of the process gas supply part 141 with the process gas supply part 141 therebetween. That is, the process gas supply part 141 includes the raw gas supply part 142 and the reaction gas supply parts, the upper dilution gas supply part 146 is disposed on one side of the process gas supply part 141 along the outer circumferences of the substrates 10 in the internal space of the reaction tube 120, and the lower dilution gas supply part 147 is disposed on the other side, which is opposite to the one side of the process gas supply part 141, along the outer circumferences of the substrates 10 in the internal space of the reaction tube 120. As described above, the upper dilution gas supply part 146 and the lower dilution gas supply part 147 may minimize a mutual influence between the flow of the dilution gas supplied by the upper dilution gas supply part 146 and the flow of the dilution gas supplied by the lower dilution gas supply part 147 even when the plurality of treatment spaces partitioned by the substrate boat 130 are not respectively formed completely and independently when the upper dilution gas supply part 146 and the lower dilution gas supply part 147 are disposed on both sides of the process gas supply part 141 with the process gas supply part 141 therebetween. FIG. 3 illustrates a structure as an example in which the process gas supply part 141 includes the raw gas supply part 142, a first reaction gas supply part 143, and a second reaction gas supply part 144, and the upper dilution gas supply part 146 and the lower dilution gas supply part 147 are disposed on both sides of the process gas supply part 141. However, the numbers and layout structures of the raw gas supply part 142 and the reaction gas supply parts may be variously changed if desired.

Further, the upper dilution gas supply holes 146H and the lower dilution gas supply holes 147H may be respectively formed in the upper dilution gas supply part 146 and the lower dilution gas supply part 147 such that a direction in which the dilution gas is supplied and a direction in which the process gas supplied from the process gas supply holes, that is, the raw gas supply holes 142H or the reaction gas supply holes 143H and 144H, is supplied, cross each other on the substrates 10. That is, the dilution gas supply part 145 may supply the dilution gas in the direction crossing the direction in which the process gas is supplied on the substrates 10 to dilute and provide the process gas for depositing the thin films on the substrates 10. Further, the substrate boat 130 is rotatably provided with the center portions of the substrates 10 as an axis as described above. As illustrated in FIG. 3, the raw gas and the reaction gas may be supplied to face the center portions C of the substrates 10 loaded in the plurality of treatment spaces, and the dilution gas may be supplied to face the center portions C of the substrates 10. Thus, the direction in which the process gas is supplied may cross the direction in which the dilution gas is supplied on the substrates 10. Here, FIG. 4A is a view illustrating a state in which the dilution gas supplied by the upper dilution gas supply part 146 crosses the raw gas supplied by the raw gas supply part 142 at the center portions C of the portion of the substrates 10 loaded in the upper treatment space, and FIG. 4B is a view illustrating a state in which the dilution gas supplied by the lower dilution gas supply part 147 crosses the raw gas supplied by the raw gas supply part 142 at the center portions C of the portion of the substrates 10 loaded in the lower treatment space.

Here, a difference may occur in reduction rate of the thicknesses of the thin films according to the amounts of the dilution gas supplied to the upper treatment space and the lower treatment space as illustrated in FIG. 5. That is, FIG. 5 is a view illustrating relative thicknesses of the thin films deposited on the substrates 10 according to the amounts of the dilution gas when the plurality of treatment spaces formed respectively for 65 substrates 10 by loading the 65 substrates 10 in the substrate boat 130 are defined as #1 to #65 treatment spaces from a lower end of the treatment spaces, the dilution gas is supplied to the #1 to #11 treatment spaces by the lower dilution gas supply part 147, and the dilution gas is supplied to the #52 to #65 treatment spaces by the lower dilution gas supply part 147. Here, a hexachlorodisilane (HCDS: Si₂Cl₆) gas is used as the raw gas, an ammonia (NH₃) gas is used as a first reaction gas, an oxygen (O₂) gas is used as a second reaction gas, and the raw gas and the reaction gas are supplied at flow rates of 4 L/min and 5 L/min, respectively. At this time, the relative thicknesses of the thin films refer to the ratios of the thicknesses of the thin films deposed when the dilution gas is supplied to the thicknesses of the thin films deposed when the dilution gas is not supplied. Although a slight difference occurs between locations at which the dilution gas is supplied, the portion of the thin films deposited in the upper treatment space have a thickness reduction rate greatly increased as the amount of the dilution gas supplied increases, while the portion of the thin films deposited in the lower treatment space have a thickness reduction rate relatively decreased as the amount of the dilution supplied gas increases, as illustrated in FIG. 4. The reason is because the exhaust port 170 is positioned on the lower portion of the internal space of the reaction tube 120, that is, a lower end of the exhaust duct 150 and because the dilution gas supplied to the lower treatment space is exhausted to the exhaust port 170 more quickly than the dilution gas supplied to the upper treatment space. Thus, the substrate treatment apparatus 100 in accordance with an exemplary embodiment further includes a control part (not illustrated) connected to the dilution gas supply part 145 to control the amount of the dilution gas supplied by the dilution gas supply part 145, and the control part may control such that the amount of the dilution gas supplied by the lower dilution gas supply part 147 is greater than the amount of the dilution gas supplied by the upper dilution gas supply part 146. Here, the control part may include a valve configured to control the amounts of respective gases whereby the thicknesses of the portion of the thin films deposited in the lower treatment space having a relatively low thickness reduction rate according to the supply of the dilution gas may be controlled to have the same thicknesses as the portion of the thin films deposited in the upper treatment space. Thus, as illustrated in a solid line in FIG. 2, thin films having a uniform thickness may be deposited on the plurality of substrates.

The exhaust duct 150 may be formed to extend in a vertical direction on the other side of the reaction tube 120, opposing the one side of the reaction tube 120 on which the process gas supply part 141 and the dilution gas supply part 145 are provided, may have an internal flow path communicating with the exhaust opening formed through the side wall of the reaction tube 120, and may be disposed opposing the process gas supply part 141 and the dilution gas supply part 145 in a space between the reaction tube 120 and the external tube 110. The exhaust duct 150 may be positioned on the other side of the reaction tube 120, may be provided on the side wall (for example, an outer wall) of the reaction tube 120, and may be disposed in the space between the reaction tube 120 and the external tube 110. At this time, the exhaust duct 150 may be positioned opposing (or symmetrical to) the process gas supply part 141 and the dilution gas supply part 145, which may allow a laminar flow to be formed on the substrates 10.

The exhaust duct 150 may be formed to extend in the vertical direction to form therein the internal flow path through which the residual gas flowed from the inside of the reaction tube 120 moves, and the internal flow path may communicate with the exhaust opening formed through the side wall of the reaction tube 120. Here, the exhaust opening may be formed as one opening or a plurality of openings, and the shape of the exhaust opening may include at least one circular shape, slit shape, or long-hole shape.

For example, the exhaust duct 150 may be formed in a quadrangular barrel shape having an internal space (that is, the internal flow path), and the residual gas flowed from the plurality of treatment spaces through the exhaust opening may move to a lower side along the internal flow path of the exhaust duct 150. Here, the lower end portion of the exhaust duct 150 may communicate (or be connected to) the exhaust port 170. That is, the exhaust port 170 may be provided to communicate with the internal space in the lower portion of the internal space of the reaction tube 120, and the exhaust duct 150 may guide the residual gas such that the residual gas may be smoothly suctioned (or exhausted) to the exhaust port 170 while preventing the residual gas from diffusing to the space between the reaction tube 120 and the external tube 110.

Further, the substrate treatment apparatus 100 in accordance with an exemplary embodiment may further include a heater part 180 provided in the direction in which the plurality of substrates are loaded, that is, a vertical direction, outside the reaction tube 120 to heat the plurality of treatment spaces. Here, the heater part 180 may extend to the outside of a receiving area of the pedestal 160. The heater part 180 may be formed to extend in a vertical direction outside the reaction tube 120 to heat the reaction tube 120, and may be disposed to surround a lateral surface and an upper portion of the reaction tube 120 or the external tube 110. Here, the heater part 180 may function to provide thermal energy to the reaction tube 120 or the external tube 110 to heat the receiving space of the reaction tube 120 and/or an internal space of the external tube 110. Thus, the temperature of the receiving space of the reaction tube 120 may be controlled to a temperature suitable for treatment of the substrates 10.

The heater part 180 may extend to the outside of the receiving area of the pedestal 160. That is, at least a portion of the heater part 180 may be provided to the outside of the receiving area of the pedestal 160. A heating region (or a region in which the heater part 180 is provided) close to a non-heating region (or a region in which the heater part 180 is not provided) loses heat by thermal equilibrium (or heat exchange) due to heat transfer even when heated by the heater part 180, and the temperature of the heating region thus becomes lower than that of other heating regions. That is, the temperature of a heating region corresponding to an edge portion of the heater part 180 becomes lower than the temperature of a heating region corresponding to a center portion of the heater part 180.

However, in accordance with an exemplary embodiment, the heater part 180 extends to the outside of the receiving area of the pedestal 160 such that the heating region corresponding to the edge portion of the heater part 180 is positioned in the receiving area of the pedestal 160. Thus, only the heating region corresponding to the center portion of the heater part 180 may be positioned in the treatment spaces in which the process of treating the substrates 10 is substantially performed. As a result, the plurality of treatment spaces may be heated more effectively.

Here, the heater part 180 may heat the upper treatment space and the lower treatment space at a temperature lower than that at which the center treatment space is heated. That is, as described above, a problem occurs in which the thin films deposited on the portions of the substrates 10 loaded in the upper treatment space and the lower treatment space have a greater thickness than the thin films deposited on the portion of the substrates 10 loaded in the center treatment space. Thus, the substrate treatment apparatus 100 in accordance with an exemplary embodiment may individually control the degrees of heating of the plurality of treatment spaces through the heater part 180, as well as supplying the dilution gas through the dilution gas supply part 145 in order to reduce the thicknesses of the thin films deposited on the portions of the substrates 10 loaded in the upper treatment space and the lower treatment space, thereby uniformly forming the thicknesses of the thin films deposited on the substrates 10 loaded in the respective treatment spaces.

Further, the substrate treatment apparatus 100 in accordance with an exemplary embodiment may further include: a chamber 190 having an upper chamber 190a and a lower chamber 190b communicating with each other; the shaft 191 connected to the lower plate 164 of the pedestal 160; a lifting part 192 connected to a lower end of the shaft 191 to vertically move the shaft 191; a rotating part 193 connected to the lower end of the shaft 191 to rotate the shaft 191; a support plate 194 connected to an upper end of the shaft 191 to be lifted with the substrate boat 130; a sealing member 194a provided between the reaction tube 120 or the external tube 110 and the support plate 194; a bearing member 194b provided between the support plate 194 and the shaft 191; and an insertion hole 195 through which the substrates 10 are loaded into the chamber 190.

The chamber 190 may be formed in a quadrangular barrel shape or a cylindrical shape, may have the external tube 110 and the reaction tube 120 disposed thereinside, and may have the upper chamber 190a and the lower chamber 190b communicating with each other.

The shaft 191 may be connected to the lower plate 164 of the pedestal 160, and may function to support the pedestal 160 and/or the substrate boat 130. Further, the lifting part may be connected to the lower end of the shaft 191 to vertically move the shaft 191, whereby the substrate boat 130 may be lifted. Here, the rotating part 193 may be connected to the lower end of the shaft 191 to rotate the substrate boat 130, and may rotate the shaft 191 to rotate the substrate boat 130 with the shaft 191 as a center axis.

The support plate 194 may be connected to the upper end of the shaft 191 to be lifted with the substrate boat 130, and may function to seal, from the outside, the internal space of the reaction tube 120 and/or the external tube 110 when the substrate boat 130 is received in the receiving space of the reaction tube 120. Further, the sealing member 194a may be provided between the support plate 194 and/or the reaction tube 120 and/or between the support plate 194 and the external tube 110, and may seal the internal space of the reaction tube 120 and/or the external tube 110.

The bearing member 194b may be provided between the support plate 194 and the shaft 191, and may rotate in a state in which the shaft 191 is supported by the bearing member 194b.

The insertion hole 195 may be provided in one side of the chamber 190 (for example, one side of the lower chamber 190b), and the substrates 10 may be loaded into the chamber 190 through the insertion hole 195 from a transfer chamber 200. An inlet 210 may be formed in one side of the transfer chamber 200 corresponding to the insertion hole 195 of the chamber 190, and a gate valve 250 may be provided between the inlet 210 and the insertion hole 195. Thus, the inside of the transfer chamber 200 and the inside of the chamber 190 may be isolated by the gate valve 250, and the inlet 210 and the insertion hole 195 may be opened and closed by the gate valve 250.

Hereinafter, a method for treating a substrate in accordance with an exemplary embodiment will be described. In the description of the method for treating a substrate in accordance with an exemplary embodiment, descriptions of the contents overlapping with those of the substrate treatment apparatus 100 described above will be omitted.

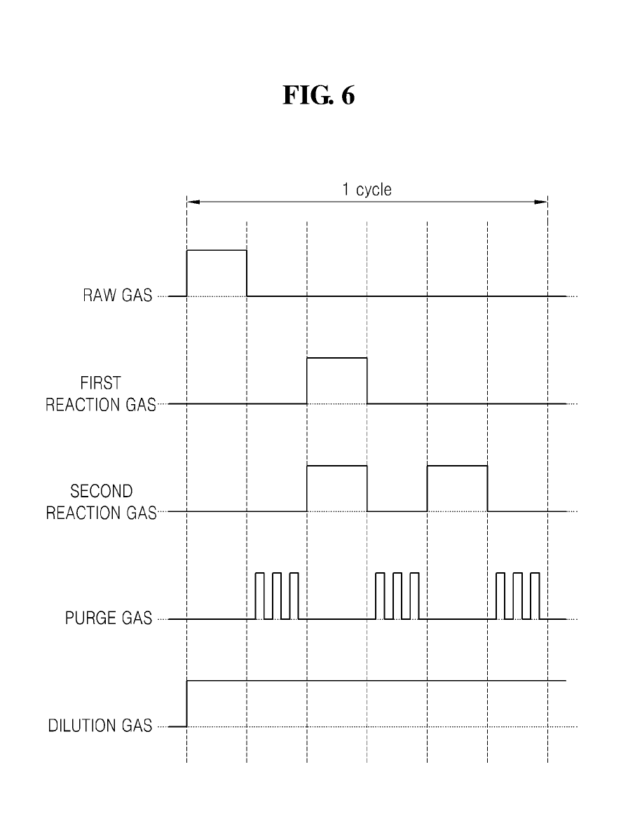

FIG. 6 is a diagram illustrating a gas supply sequence of a substrate treatment method in accordance with an exemplary embodiment.

Referring to FIG. 6, the substrate treatment method in accordance with an exemplary embodiment includes: respectively positioning the plurality of substrates 10 in the plurality of treatment spaces disposed in multi-stages; and forming the thin films on the plurality of substrates 10 by supplying the process gas to the plurality of treatment spaces. The forming of the thin films includes supplying the dilution gas for diluting the process gas within the treatment spaces.

First, the respective positioning of the plurality of substrates 10 in the plurality of treatment spaces disposed in multi-stages includes loading the plurality of substrates 10 in the substrate boat 130 and positioning, in the internal space of the reaction tube 120, the substrate boat 130 in which the plurality of substrates 10 are loaded. Thus, the substrate boat 130 is positioned in the internal space of the reaction tube 120, and the plurality of treatment spaces are partitioned. Here, the treatment spaces refer to spaces in which the process of treating the substrates 10 is individually performed as described above.

The forming of the thin films includes supplying the process gas to each of the plurality of treatment spaces and forming the thin films on the plurality of substrates 10. The forming of the thin films is not limited thereto, but is performed by an atomic layer deposition (ALD) process. In this case, the forming of the thin films may include: supplying the raw gas to the plurality of treatment spaces; purging the raw gas remaining in the plurality of treatment spaces; supplying the reaction gas to the plurality of treatment spaces; and purging the reaction gas remaining in the plurality of treatment spaces.

Here, a chlorosilane-based gas, for example, a hexachlorodisilane (HCDS: Si₂Cl₆) gas is used as the raw gas, and an ammonia (NH₃) gas and an oxygen (O₂) gas are used as the first reaction gas and the second reaction gas.

The supplying of the raw gas to the plurality of treatment spaces includes supplying the raw gas to each of the plurality of treatment spaces through the raw gas supply part 142. At this time, a chemically stable gas such as a nitrogen (N₂) gas may be supplied by the first reaction gas supply part 143 and the second reaction gas supply part 144 disposed on both sides of the raw gas supply part 142 during the supply of the raw gas, if desired. Here, the chemically stable gas refers to a gas having a very low reactivity in a monoatomic or molecular state, and may include an inert gas.

The substrate treatment method, in accordance with an exemplary embodiment, includes the forming of the thin films that includes the supplying of the dilution gas. Here, the supplying of the dilution gas includes supplying the dilution gas through a path distinct from that for the process gas, and the supplying of the process gas and the supplying of the dilution gas are performed together. Here, when the forming of the thin films includes the supplying of the raw gas, the purging of the raw gas, the supplying of the reaction gas, and the purging of the reaction gas, the supplying of the dilution gas may be performed at least together with the supplying of the raw gas. The reason is because the thicknesses of the thin films deposited on the substrates 10 loaded in the treatment spaces are primarily determined by the supply of the raw gas, and the supplying of the dilution gas may be performed at least together with the supplying of the raw gas. However, the supplying of the dilution gas may be performed together with at least one of the purging of the raw gas, the supplying of the reaction gas, or the purging of the reaction gas in addition to the supplying of the raw gas. In this case, the thicknesses of the thin films deposited may be controlled more efficiently by reducing the concentration of the reaction gas supplied to at least one of the upper treatment space or the lower treatment space or improving purge efficiency. Here, the raw gas or a chemically stable gas that does not react with the raw gas and the reaction gas may be used as the dilution gas, and the chemically stable gas may include a nitrogen (N₂) gas. As described above, when the nitrogen (N₂) gas is used as the dilution gas, the dilution gas may be prevented from reacting with the raw gas and the reaction gas, and, in addition, an element included in silicon oxide (SiO₂) thin films doped with nitrogen (N) to be deposited is used as the dilution gas in depositing the silicon oxide (SiO₂) thin films. Thus, even when a trace amount of the dilution gas reacts with the raw gas or the reaction gas or is adsorbed onto the substrates 10, impurities other than an element that forms the thin films may be prevented from being included in the thin film.

Here, the plurality of treatment spaces may be divided into the upper treatment space, the center treatment space, and the lower treatment space in the direction in which the plurality of substrates 10 are loaded in the substrate boat 130. In this case, the supplying of the dilution gas may include supplying the dilution gas to at least one of the upper treatment space or the lower treatment space, thereby individually controlling the thicknesses of the portions of the thin films deposited in the upper treatment space and the lower treatment space as described above.

The purging of the raw gas remaining in the plurality of treatment spaces includes stopping the supply of the raw gas through the raw gas supply part 142 and supplying the purge gas by the raw gas supply part 142, the first reaction gas supply part 143, and the second reaction gas supply part 144 to purge the raw gas remaining in the plurality of treatment spaces. That is, the purge gas is supplied by the raw gas supply part 142, the first reaction gas supply part 143, and the second reaction gas supply part 144, and has a supply path different from that for the dilution gas supplied by at least one of the upper dilution gas supply part 146 or the lower dilution gas supply part 147. Thus, the dilution gas is supplied to the upper treatment space or the lower treatment space through the supply path different from that for the purge gas, whereby the process gas may be independently diluted regardless of whether the raw gas, the reaction gas or the purge gas is supplied.

Here, the purging of the raw gas may be performed by repeating supply and shutoff of the purge gas to the plurality of treatment spaces multiple times while the plurality of treatment spaces are exhausted. That is, the purging of the raw gas is performed by alternately repeating supply and shutoff of the purge gas, for example, a chemically stable gas such as a nitrogen (N₂) gas, to the plurality of treatment spaces while exhausting the internal space of the reaction tube 120 in order to create a vacuum in the internal space of the reaction tube 120. As described above, the plurality of treatment spaces may be quickly decompressed by performing the purging of the raw gas through repeating the supply and shutoff of the purge gas to the plurality of treatment spaces multiple times while exhausting the plurality of treatment spaces, and the raw gas remaining in the plurality of treatment spaces may be sufficiently replaced with a chemically stable gas.

The supplying of the reaction gas to the plurality of treatment spaces includes stopping supply of the purge gas by the reaction gas supply parts and supplying the reaction gas to each of the plurality of treatment spaces through the reaction gas supply parts. Here, the reaction gas supply parts may include the first reaction gas supply part 143 and the second reaction gas supply part 144. In this case, the supplying of the reaction gas to the plurality of treatment spaces may include: supplying the first reaction gas; purging the remaining first reaction gas; and supplying the second reaction gas. However, the supplying of the reaction gas in the substrate treatment method in accordance with an exemplary embodiment may include: simultaneously supplying, to the plurality of treatment spaces, the first reaction gas and the second reaction gas interacting with each other; and solely supplying the second reaction gas to the plurality of treatment spaces. As described above, when the ammonia (NH₃) gas is used as the first reaction gas, the nitrogen (N) included in the ammonia (NH₃) has a high reactivity. Thus, when the first reaction gas is solely supplied, the content of the nitrogen (N) contained in the thin films becomes unnecessarily high. Thus, the first reaction gas including the ammonia (NH₃) gas and the second reaction gas including the oxygen (O₂) gas may be simultaneously supplied to control the content of the nitrogen (N) contained in the thin films. Further, as described above, since the nitrogen (N) has a high reactivity, a high concentration of nitrogen (N) is contained in the thin films even when the first reaction gas including the ammonia (NH₃) gas and the second reaction gas including the oxygen (O₂) gas are simultaneously supplied. Thus, the second reaction gas may be solely supplied after the simultaneous supplying of the first reaction gas and the second reaction gas to increase the content of oxygen (O) contained in the thin films and improve the thickness distribution of the thin films, thereby depositing the thin films having a uniform thickness on the substrates. Here, the simultaneous supplying of the first reaction gas and the second reaction gas and the sole supplying of the second reaction gas may include therebetween purging the simultaneously supplied first and second reaction gases. In this case, the purging of the first reaction gas and the second reaction gas may be performed by repeating the supply and shutoff of the purge gas to the plurality of treatment spaces multiple times while exhausting the plurality of treatment spaces as described above.

The purging of the reaction gas remaining in the plurality of treatment spaces includes stopping the supply of the reaction gas through the reaction gas supply parts, supplying the purge gas by the raw gas supply part 142, the first reaction gas supply part 143, and the second reaction gas supply part 144, and purging the reaction gas remaining in the plurality of treatment spaces. Here, the purging of the reaction gas may be performed by repeating the supply and shutoff of the purge gas to the plurality of treatment spaces multiple times while exhausting the plurality of treatment spaces as described above. The supplying of the raw gas, the purging of the raw gas, the supplying of the reaction gas, and the purging of the reaction gas is set to one cycle. The silicon oxide (SiO₂) thin films doped with the nitrogen (N) may be deposited on the substrates 10 respectively loaded in the plurality of treatment spaces by repeating the cycle multiple times.

As described above, the substrate treatment apparatus 100 and the substrate treatment method in accordance with the exemplary embodiments, may supply the dilution gas together with the process gas to the plurality of treatment spaces partitioned by the substrate boat 130, thereby controlling the concentration of the process gas, and may supply the dilution gas to the portion of the plurality of treatment spaces to adjust the concentration of the process gas in each treatment space, thereby individually controlling the thicknesses of the thin films deposited on the plurality of substrates 10 loaded.

That is, the thicknesses of the thin films deposited on the substrates 10 loaded in each treatment space may be made uniform regardless of the presence of the process gas staying the extra internal spaces formed in upper portions and lower portions of the plurality of treatment spaces within the reaction tube 120 of a longitudinal type, and, even when the process gas flowed from the lower end of the process gas supply part 141 is discharged through the exhaust port 170 positioned in the lower portion of the internal space via the plurality of treatment spaces, the thicknesses of the portions of the thin films deposited in the upper treatment space and the lower treatment space may be made uniform with that of a portion of the thin films deposited in the center treatment space. Furthermore, even when substrates of a type different from that of the substrates 10 to be treated are loaded in the upper end portion and the lower end portion of the substrate boat 130, uniform thin films may be formed on the substrates 10 to be treated, respectively, thereby increasing quality of the formed thin films and the substrates 10, on which the thin films are formed.

Further, the upper dilution gas supply part 146 configured to supply the dilution gas to the upper treatment space of the plurality of treatment spaces and the lower dilution gas supply part 147 configured to supply the dilution gas to the lower treatment space thereof may be separately disposed, thereby independently controlling the concentrations of the process gas supplied to the upper treatment space and the lower treatment space, and the direction in which the process gas is supplied and the direction in which the dilution gas is supplied may be crossed on the substrates 10, thereby efficiently mixing, with the dilution gas, the process supplied to the respective substrates 10.

Moreover, in supplying different types of reaction gases during deposition of the thin films using the ALD process, mixing of the first reaction gas with the second reaction gas, supplying of the mixture, and independent supplying of the second reaction gas may be sequentially performed, thereby effectively controlling the content of the element contained in the thin films from the first reaction gas, and, the plurality of treatment spaces may be quickly depressurized and the raw gas remaining in each treatment space may be effectively and sufficiently replaced with the stable gas by repeating the supply and shutoff of the purge gas to the plurality of treatment spaces multiple times while exhausting the plurality of treatment spaces in the purging of the raw gas or the reaction gas.

In the above, although the exemplary embodiments of the present invention have been illustrated and described using specific terms, such terms are merely for the purpose of clarifying the invention. It would be obvious that various changes and modifications may be made to the embodiments and terms of the invention without departing from the spirit and scope of the following claims. Such modified embodiments should not be individually understood from the spirit and scope of the present invention, but should be construed as being within the claims of the present invention.

What is claimed is:

1. A substrate treatment apparatus comprising:
a reaction tube having an internal space formed therein;
a substrate boat configured to load a plurality of substrates in multi-stages, and positioned in the internal space to partition a plurality of treatment spaces in which the plurality of substrates are respectively treated;
a process gas supply part configured to supply a process gas to the plurality of treatment spaces; and
a dilution gas supply part configured to supply a dilution gas for diluting the process gas within the plurality of treatment spaces.

2. The substrate treatment apparatus of claim 1, wherein the process gas supply part supplies the process gas to each of the plurality of treatment spaces, and the dilution gas supply part supplies the dilution gas to a portion of the plurality of treatment spaces.

3. The substrate treatment apparatus of claim 1, wherein the plurality of treatment spaces are divided into an upper treatment space, a center treatment space, and a lower treatment space in a direction in which the plurality of substrates are loaded, and the dilution gas supply part supplies the dilution gas to at least one of the upper treatment space or the lower treatment space.

4. The substrate treatment apparatus of claim 3, wherein the dilution gas supply part comprises: an upper dilution gas supply part having an upper dilution gas supply hole corresponding to the upper treatment space; and a lower dilution gas supply part having a lower dilution gas supply hole corresponding to the lower treatment space.

5. The substrate treatment apparatus of claim 1, further comprising: an exhaust duct disposed opposing the process gas supply part, and formed to extend vertically in a direction in which the plurality of substrates are loaded; and an exhaust port configured to communicate with a lower end of the exhaust duct,
the process gas supply part being formed to extend vertically in the direction in which the plurality of substrates are loaded, and
the process gas flowing from a lower end of the process gas supply part to an upper end thereof, passing through each of the plurality of treatment spaces, flowing from an upper end of the exhaust duct to the lower end thereof, and being exhausted through the exhaust port.

6. The substrate treatment apparatus of claim 1, wherein dummy substrates are loaded on an upper end portion and a lower end portion of the substrate boat, and the plurality of treatment spaces are provided between the upper end portion and the lower end portion of the substrate boat.

7. The substrate treatment apparatus of claim 1, wherein the dilution gas supply part supplies the dilution gas in a direction crossing a direction in which the process gas is supplied on the plurality of substrates.

8. The substrate treatment apparatus of claim 4, further comprising a control part connected to the dilution gas supply part, and configured to control the amount of the dilution gas supplied by the dilution gas supply part,
the control part being configured to control such that the amount of the dilution gas supplied by the lower dilution gas supply part is greater than the amount of the dilution gas supplied by the upper dilution gas supply part.

9. The substrate treatment apparatus of claim 3, further comprising a heater part provided outside the reaction tube in the direction in which the plurality of substrates are loaded, and configured to heat the plurality of treatment spaces,
the heater part being configured to heat the upper treatment space and the lower treatment space at a temperature lower than that at which the center treatment space is heated.

10. A substrate treatment method comprising:
respectively positioning a plurality of substrates in a plurality of treatment spaces disposed in multi-stages; and
forming thin films on the plurality of substrates by supplying a process gas to the plurality of treatment spaces,
wherein the forming of the thin films comprises supplying a dilution gas for diluting the process gas within the plurality of treatment spaces.

11. The substrate treatment method of claim 10, wherein the forming of the thin films further comprises: supplying a raw gas to the plurality of treatment spaces; purging the raw gas remaining in the plurality of treatment spaces; supplying a reaction gas to the plurality of treatment spaces; and purging the reaction gas remaining in the plurality of treatment spaces, and
the supplying of the dilution gas is performed at least together with the supplying of the raw gas.

12. The substrate treatment method of claim 10, wherein the plurality of treatment spaces are divided into an upper treatment space, a center treatment space, and a lower treatment space in a direction in which the plurality of substrates are loaded, and the supplying of the dilution gas comprises supplying the dilution gas to at least one of the upper treatment space or the lower treatment space.

13. The substrate treatment method of claim 11, wherein the purging of the raw gas and the purging of the reaction gas are performed by repeating supply and shutoff of a purge gas to the plurality of treatment spaces multiple times while exhausting the plurality of treatment spaces.

14. The substrate treatment method of claim 13, wherein the dilution gas and the purge gas each comprise a gas chemically stable with respect to the raw gas and the reaction gas, and the supplying of the dilution gas comprises supplying the dilution gas to the plurality of treatment spaces through a path different from that through which the purge gas is supplied thereto.

15. The substrate treatment method of claim 11, wherein the supplying of the reaction gas comprises: simultaneously supplying a first reaction gas and a second reaction gas to the plurality of treatment spaces; and solely supplying the second reaction gas to the plurality of treatment spaces.
